(19) United States
(12) Patent Application Publication
(10) Pub. No.: US 2026/0164871 A1
(43) Pub. Date: Jun. 11, 2026

(54) OPTOELECTRONIC LIGHTING DEVICE

(71) Applicant: ams-OSRAM International GmbH, Regensburg (DE)

(72) Inventors: Daniel Richter, Abbach (DE); Gunnar Petersen, Regensburg (DE)

(21) Appl. No.: 18/712,414

(22) PCT Filed: Nov. 24, 2022
(86) PCT No.: PCT/EP2022/083209

§ 371 Date: May 22, 2024

(30) Foreign Application Priority Data
Nov. 25, 2021 (DE) 10 2021 130 998.0

(51) Int. Cl. H10H 20/858; H10H 20/841

(52) U.S. Cl. CPC H10H 20/8581; H10H 20/841

(57) ABSTRACT

In an embodiment an optoelectronic lighting device at least one optoelectronic light source configured to generate light, at least one conversion system configured to convert the light into converted light, a thermally conductive substrate, wherein the conversion system is arranged on the substrate for heat dissipation, wherein the light source is also arranged on the substrate above the conversion system or laterally next to the conversion system, and a mirror coating arranged above the light source, wherein the mirror coating is transparent to the converted light and/or reflective to the light, wherein the conversion system includes a polymer matrix material in which a converter material and particles, which are substantially transparent to a wavelength of the converted light, are embedded, and which have a thermal conductivity which is at least 20 times higher than a thermal conductivity of the polymer matrix material.

### CROSS-REFERENCE TO RELATED APPLICATIONS

This patent application is a national phase filing under section 371 of PCT/EP2022/083209, filed Nov. 24, 2022, which claims the priority of German patent application 10 2021 130 998.0, filed Nov. 25, 2021, each of which is incorporated herein by reference in its entirety.

### TECHNICAL FIELD

The present invention relates to an optoelectronic lighting device comprising at least one optoelectronic light source for generating light, at least one conversion system for generating converted light by converting the light provided by the light source, and a substrate.

### BACKGROUND

It has been found that converter solutions for broadband IR conversion in particular suffer greatly from thermal quenching. For common components, the output power of a component drops again at pulse lengths of 200 ms and currents greater than 700 mA. In addition to further phosphor development, the main lever for further improving the products is to optimize the thermal bonding of the phosphor and thus shift the operating point. Although measures have already been developed to reduce the thermal load, further problems have arisen as a result.

### SUMMARY

Embodiments provide an improved optoelectronic lighting device which, in particular, permits stable operation even at higher light outputs and/or exhibits improved brightness.

The inventors are now proposing not only to bring the converter as close as possible to a heat sink, but also to further improve the thermal conductivity of the converter. The polymer material in particular has proven to be an obstructive factor here, as it has poor thermal performance and can only transport the heat generated by the light source poorly.

Accordingly, in one aspect an optoelectronic lighting device is proposed which has at least one optoelectronic light source for generating light, at least one conversion system for generating converted light by converting the light provided by the light source, and a substrate, in particular a thermally conductive substrate, wherein the conversion system is arranged on the substrate for better heat dissipation and the light source is arranged above the conversion system or is also arranged on the substrate laterally next to the conversion system. In addition to a polymer matrix material and the converter material embedded therein, in particular phosphors, the conversion system according to the proposed principle also comprises a further material which has a high thermal conductivity-greater than that of the polymer matrix material.

In other words, the polymer matrix material is at least partially replaced by particles which have a high transmittance in the relevant wavelength range and a refractive index as close as possible to the polymer matrix material. The replacing particles also have the highest possible thermal conductivity, which is in particular greater than the polymer matrix material. This minimizes any negative influence on light extraction and optimizes heat removal.

By improving the dissipation of heat from the conversion system, heat-related effects that cause a deterioration in the conversion can be avoided or at least reduced. In particular, the effect of “thermal quenching” can be reduced or avoided. This effect causes the intensity of the converted light to decrease at higher pump powers, i.e. at a higher intensity of the light provided by the light source and correspondingly at higher currents through the light source. Thanks to the improved thermal connection of the converter, such a drop in intensity at higher currents through the light source can be avoided or at least reduced. This means that higher light outputs can also be achieved.

In some aspects, particles based on elements of the VII main group, i.e., F, Cl, or I, are proposed. Possible particle materials consist of or comprise LiF, lithium fluoride; MgF2, magnesium fluoride; CaF2, calcium fluoride; BaF2, barium fluoride; and sapphire. The amount of these particles may range from 10% to 50% by weight. In particular, between 20% and 80% by weight of the polymer matrix material may have been replaced by such particles.

In some aspects, the particles have an average size that is smaller than the particles of the converter material. In this context, the particles are characterized by an average size that is only half the average size of the converter material. In general, it is useful to have the particles as small as possible, since in this way more polymer matrix material can be replaced. in some aspects, the particles have an average size in the range from 30 nm to 200 nm, in particular smaller than 150 nm.

The thermal conductivity of the particles is greater than 40 times and in particular greater than 50 times the thermal conductivity of the polymer matrix material. In contrast, the refractive index of the particles differs from that of the polymer matrix material by only 0.03 to 0.1, and in particular less than 0.1.

In some aspects, the particles are provided with a very thin coating to achieve improved adhesion to the surrounding polymer. Such a coating is in some aspects also designed as a water barrier so that the particles are protected from moisture. This improves the long-term stability.

The particles can be randomly distributed in the conversion system. However, it is also possible to store the particles in the conversion system in the form of layers or in another organized manner. In some embodiments, this allows directed heat transport.

Further aspects deal with the structure of the proposed arrangement. For example, a mirror coating, in particular in the form of a Bragg mirror, can be arranged above the light source, in particular on the upper surface of the light source, whereby the mirror coating is transparent for the converted light and reflects the light generated by the light source.

Unwanted upward radiation of the light provided by the light source can thus be avoided. In addition, the light provided by the light source can be reflected into the converter by the mirror coating. As the mirror coating is transparent for the converted light, the converted light can be emitted upwards. In particular, the light source can also be transparent to the converted light. The sealing can also be realized in the classic way, for example by means of a mirror layer.

According to at least one embodiment of the proposed principle, the term “transparent” or the term “transmittance” or also “transparency” means a transmittance of at least 50%, 60%, 70%, 80%, 90%, 95%, 98% or 99% with respect to an incident light intensity.

According to at least one embodiment of the proposed principle, the term “reflected” or the term “reflectance” or also “reflectivity” can mean a reflectivity of at least 50%, 60%, 70%, 80%, 90%, 95%, 98% or 99% in relation to an incident light intensity.

The mirror coating can be designed as a layer that extends at least essentially over the entire length and width of the device. This is an efficient way of preventing light provided by the light source from escaping upwards out of the device. Alternatively, the mirror coating can only extend over the entire upper surface of the light source.

The light source can have overhead electrical contacts for the power supply. The electrical contacts can be designed as planar contacts that run in a plane parallel to the upper surface of the substrate. The electrical contacts can also be designed as a bonding wire. Since the electrical contacts are located at the upper surface of the light source, the bottom surface of the light source can be arranged directly on the conversion system. If it is intended that the light source is arranged next to the conversion system, the bottom surface of the light source can be arranged directly on the substrate, and good heat dissipation for the heat generated in the light source can be achieved via the substrate.

The device may have an encapsulation extending circumferentially around the conversion system and/or around the light source, preferably the encapsulation reflecting the converted light and/or the light provided by the light source. The encapsulation allows more of the light from the light source to be brought into the converter and thus converted. Furthermore, the upward light emission of the converted light can be improved.

If the light source is arranged to the side of the conversion system on the substrate, at least two conversion systems can be provided and the light source can be arranged between the two conversion systems. Efficient conversion of the light provided by the light source into converted light can thus be achieved.

An upper surface of the substrate, on which the conversion system is arranged, can have a flat area and a rising area adjoining the flat area, whereby the conversion system is arranged at least on the rising area and preferably also on the flat area. Due to the rising area of the substrate, converted light can be reflected upwards in an improved manner and thus a higher light emission efficiency can be achieved at the upper surface of the lighting device. The substrate can have a high reflectivity for converted light and/or for the light provided by the light source.

The light source can be arranged above the flat area and an upper surface of the light source can face the rising area. An efficient application of light from the light source to the converter can thus be realized.

The upper surface of the light source can be aligned perpendicular to the surface of the flat area of the substrate. The bottom surface of the light source can be attached to a wall that is perpendicular to the flat area of the substrate. The wall can be a wall of a submount, for example, which can provide electrical connections for the light source. Preferably, the light source is designed as a flip chip.

The proposed principle also relates to an optoelectronic lighting device which has at least one optoelectronic light source for generating light, at least one conversion system for generating converted light by converting the light from the light source, and a substrate, in particular a thermally conductive substrate, wherein the light source is arranged laterally next to the conversion system and a light-conducting layer, in particular with a grating structure, is formed between the substrate and the light source in order to guide the light provided by the light source to the converter. Improved coupling and/or decoupling can be achieved via the grating structure. The grating structure can be formed by trenches running parallel to each other, which are introduced into the light-conducting layer. The conversion system is again realized as presented in this application.

Using the light-conducting layer, the light generated by the light source can be efficiently directed to the conversion system. As a result, an increased luminous efficacy of converted light can be achieved.

The light-conducting layer can be arranged on the substrate and the conversion system and the light source can be arranged on the light-conducting layer. This allows a particularly compact arrangement to be realized.

According to at least one embodiment, at least two conversion systems can be provided, and the light source can be arranged between the two conversion systems, wherein an encapsulation is arranged between the light source and a respective conversion system, wherein, preferably, the encapsulation reflects the converted light and the light provided by the light source. An efficient conversion of the light provided by the light source into converted light can thus be achieved.

Furthermore, an optoelectronic lighting device is proposed which has at least one optoelectronic light source for generating light, at least one conversion system according to the proposed principle for generating converted light by converting the light from the light source, and a substrate, in particular a thermally conductive substrate, at least one heat-conducting layer being provided above the conversion system, in particular directly above or below the conversion system, for dissipating heat from the conversion system. By means of the heat conducting layer, efficient dissipation of the heat generated in the converter can be achieved. This is improved by the presence of particles with high thermal conductivity. The heat-conducting layer is preferably designed as a transparent layer so that converted light can be emitted upwards out of the device through the heat-conducting layer.

The light source can be arranged on the substrate and the conversion system can be arranged above the light source. In particular, the conversion system can be arranged directly on the light source. The light source can also be arranged directly on the substrate. The substrate can provide electrical contacts to which the electrical contacts of the light source can be connected. Preferably, the light source is designed as a flip chip, so that both electrical contacts of the light source are located on the bottom surface and can be connected directly to electrical contacts on the substrate.

In some aspects, the upper surface of the light source may be flat and the conversion system may be located directly on the flat upper surface of the light source. Direct coupling of the light generated by the light source into the converter can thus be achieved.

An encapsulation can extend circumferentially around the light source and under the conversion system, with the encapsulation reflecting the converted light and the light provided by the light source. This allows the light generated by the light source to be brought into the converter in an improved manner. In addition, the efficiency of the upward emission of converted light can be improved.

The outer edge of the heat conducting layer can be in thermal contact with a housing wall of the device. Heat build-up in the heat conducting layer can thus be avoided.

The proposed principle also includes an optoelectronic lighting device which has at least one optoelectronic light source for generating light, at least one conversion system for generating converted light by converting the light from the light source, and a substrate, in particular a thermally conductive substrate, wherein one or more, in particular transparent, heat-conducting layers are arranged in the conversion system for dissipating heat from the conversion system. In some aspects, these heat-conducting layers comprise optically inactive particles whose refractive index is, on the one hand, close to the polymer matrix material of the conversion system and, on the other hand, is characterized by a significantly higher thermal conductivity, in particular higher than by a factor of 20. The optically inactive particles can comprise the elements of the VII main group described above.

The heat conducting layer improves the dissipation of heat from the conversion system. Unwanted thermal effects in the converter can therefore be avoided or at least reduced.

The proposed principle also relates to an optoelectronic lighting device which has at least one optoelectronic light source for generating light, at least one conversion system for generating converted light by converting the light from the light source, and a substrate, in particular a thermally conductive substrate, wherein at least one and preferably several, in particular non-transparent, heat-conducting elements are arranged in the conversion system for dissipating heat from the conversion system. The particles allow particularly good thermal coupling to the heat-conducting elements. In combination with the high thermal conductivity of the particles, undesirable thermal effects in the converter can also be avoided or at least reduced by the heat conducting elements.

A respective heat conducting element can protrude through the converter when viewed in a vertical direction, with the vertical direction running perpendicular to the upper surface of the substrate. Efficient heat dissipation over the entire height of the converter can thus be achieved.

A respective heat conducting element can have a triangular cross-section. Due to the triangular cross-section of the heat-conducting elements, a respective element is particularly suitable as a reflector for the light provided by the light source and/or for the converted light.

A respective heat conducting element can be designed as an elongated, rod-shaped element. Such heat conducting rods can be fully or partially immersed in the converter parallel to each other and at a distance from each other. Good heat dissipation can be achieved in a structure consisting of a converter and immersed heat conducting rods.

A respective heat conducting element can be made of a metal, such as copper, silver or gold. A respective heat conducting element can be designed to be highly reflective for the light provided by the light source and/or for the converted light.

The conversion system can be designed as a converter plate with a rectangular cross-section, for example. Converter materials of the conversion system are known per se and have optically active materials which can convert light of a first wavelength into at least one other, second wavelength in a manner known per se, wherein the second wavelength is greater than the first wavelength.

The light source can be an LED or an LED chip. LED stands for light emitting diode.

The light source can be an optoelectronic laser, such as a laser diode or a VCSEL. VCSEL stands for Vertical Cavity Surface Emitting Laser. Such lasers are well known.

For example, the light source can emit blue light, which is converted by the conversion system into light of a different color, such as red light or infrared light or white light. The term “light” is not limited to the visible spectral range, but also includes electromagnetic radiation outside the visible spectrum, such as infrared or ultraviolet light.

Features disclosed in combination with one embodiment herein may also be realized in another embodiment, even if this is not explicitly disclosed herein.

### BRIEF DESCRIPTION OF THE DRAWINGS

The invention is described in more detail below by way of example and with reference to the accompanying drawings.

FIG. 1A shows a lateral sectional view of a variant of an optoelectronic lighting device;

FIG. 1B shows a side sectional view of a second variant of an optoelectronic lighting device;

FIG. 2 shows a top view of the device of FIG. 1;

FIG. 3 shows a lateral sectional view of a further variant of an optoelectronic lighting device

FIG. 4 shows a top view of the device of FIG. 3;

FIG. 5 shows a lateral sectional view of a further variant of an optoelectronic lighting device;

FIG. 6 shows a top view of the device of FIG. 5;

FIG. 7 shows a lateral sectional view of a further variant of an optoelectronic lighting device;

FIG. 8 shows a lateral sectional view of a further variant of an optoelectronic lighting device;

FIG. 9 shows a top view of the device of FIG. 8;

FIG. 10 shows a lateral sectional view of a further variant of an optoelectronic lighting device;

FIG. 11 shows a top view of the device of FIG. 10;

FIG. 12A shows a lateral sectional view of yet another variant of an optoelectronic lighting device;

FIG. 12B shows a side sectional view of yet another variant of an optoelectronic lighting device;

FIG. 13 shows a top view of the device of FIG. 12;

FIG. 14 shows a lateral sectional view of yet another variant of an optoelectronic lighting device; and

FIG. 15 shows a top view of the device of FIG. 14.

### DETAILED DESCRIPTION OF ILLUSTRATIVE EMBODIMENTS

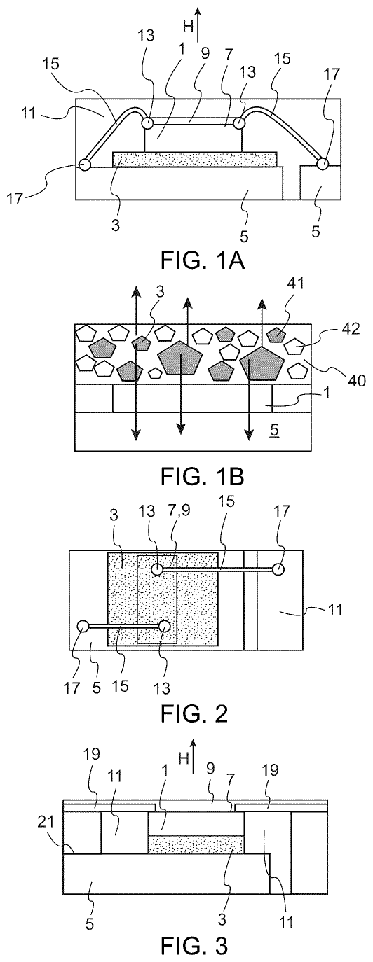

The optoelectronic lighting device shown in FIGS. 1A, 1B and 2 comprises an optoelectronic light source 1, such as an LED or a laser diode, for generating light, for example blue light, at least one conversion system 3 for generating converted light, for example infrared light, by converting the light provided by the light source 1, and a thermally conductive substrate 5. The conversion system 3 is arranged on the substrate 5 for better heat dissipation. The light source 1 is arranged above the converter 3 so that the heat generated in the light source 1 can be dissipated via the converter 3 and into the substrate 5. In addition to the converter material, the conversion system also comprises particles of a fluoride, e.g. NaF2 or BaF2, which have a conductivity that is 30 to 70 times or substantially higher than the conductivity of a polymer matrix material in which the converter material and the particles are embedded. The particles are optically inactive, i.e. essentially transparent. In addition, they have approximately the same refractive index as the polymer matrix material, so that no additional refractive index jump can occur.

The improved heat dissipation means that heat-related effects, such as thermal quenching, can be avoided or at least reduced. At least in some embodiments, higher currents through the light source 1, which result in a higher intensity of the light provided from the light source, hereinafter also referred to as pump light, therefore do not lead to a decrease in the intensity of the converted light. By thermally connecting the conversion system 3 with the additional heat-conducting particles directly to the substrate 5, such a drop in intensity at higher intensities of the pump light can be avoided or at least reduced. Higher light outputs in relation to the converted light are therefore possible. In addition, stable operation of the device can be achieved.

A mirror coating 9 is arranged directly on the upper surface 7 of the light source 1. The mirror coating 9 can be in the form of a coating and, for example, a Bragg mirror. The mirror coating 9 can be transparent for the converted light so that the converted light can be emitted upwards in the direction of a main emission direction H. The mirror coating 9 can reflect the light provided by the light source so that this light is directed into the converter 3.

The light exit area for the converted light can correspond to the surface of the upper surface 7 of the light source 1. The remaining area of the upper surface of the device can be covered by a housing wall (not shown). The device can also be enclosed by housing walls on the lateral outer surfaces and on the bottom surface (not shown). The optional housing may be part of the device.

The device also has an encapsulation 11 that surrounds the conversion system 3 and the light source 1. In particular, the encapsulation 11 can fill a remaining volume between the substrate 5 and the light-emitting surface. The encapsulation 11 can reflect the pump light. In particular, the encapsulation 11 can be designed to be highly reflective for the occurring wavelengths of the pump light.

So that the light source 1 can be arranged directly on the conversion system 3, the two electrical contacts 13 of the light source 1 are arranged on the bottom surface, which faces upwards in the illustration according to FIG. 1. A respective contact 13 is connected to an electrical contact 17 on the substrate 5 via a respective bonding wire 15.

The light source 1 can be an LED, for example, which is designed as a flip chip. The flip chip can be designed as a surface emitter that emits the pump light on its upper surface. However, it can also be designed as a volume emitter, in which case light is emitted not only on the upper surface but also on the side surfaces.

FIG. 1B shows a variant that also illustrates the structure of the conversion system as an example in an enlarged view. In this case, the conversion system is arranged on the light source and not between the substrate 5 and the light source 1 as in the first embodiment example. This is made possible by the structure of the conversion system 3 according to the proposed principle. On the one hand, the conversion material comprises a polymer matrix material 40, which is composed of a silicone or another transparent material. Embedded therein is a converter material 41, which converts irradiated pump light of a first wavelength into light of a second wavelength. As shown here, the converter material is formed from converter particles, which in turn are not all the same size, but have a certain size distribution. This is indicated by the two differently sized particles 40.

Although silicone as a polymer matrix material has the necessary good optical properties, it has poor thermal conductivity. For this reason, additional particles 42 with a significantly higher thermal conductivity are embedded in the polymer matrix material. The particles 42 have a refractive index that is similar to the refractive index of the polymer matrix material. The difference between the two refractive indices is less than 0.1 and is in the range from 0.03 to 0.07.

The particles introduced are smaller than the average size of the converter materials, so that the density of the particles is in some aspects even greater than the density of the converter materials. In addition, the smaller average size allows a large proportion of the polymer matrix material to be exchanged, thereby increasing the thermal conductivity. In the example embodiment, approximately 50% to 70% of the polymer material is exchanged, but larger values are also possible. The mechanical stability is maintained by the polymer matrix material or is not impaired by the exchange with particles.

In this way, the converted light, represented by the arrows pointing upwards, is emitted. The increased thermal conductivity of the conversion system allows the heat generated in system 3 to be dissipated through the light source onto the substrate as a heat sink.

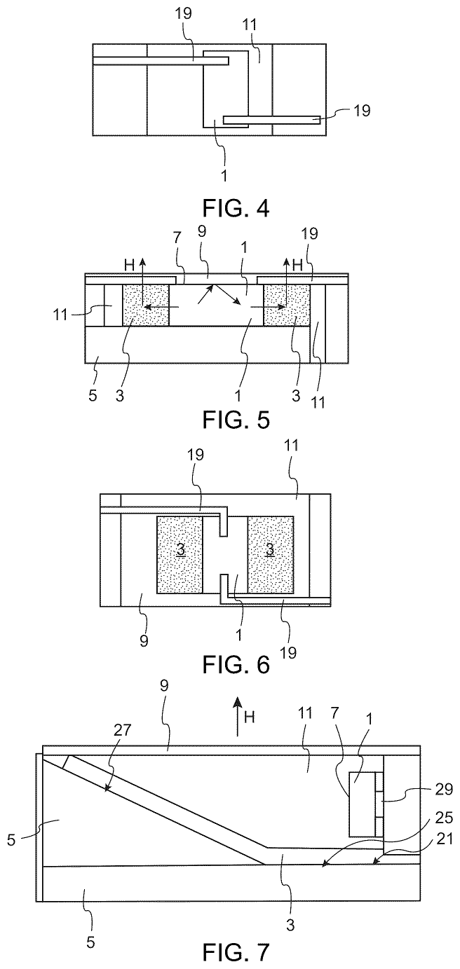

The variant of FIGS. 3 and 4 differs from the device described above in that the mirror coating 9 is designed as a layer that extends at least essentially over the entire length and width of the device. The mirror coating 9 is arranged directly on the upper surface 7 of the light source 1. The encapsulation 11 surrounds the light source 1 and the conversion system 3, but does not cover the upper surface of the light source 1. The encapsulation 11 can therefore be highly reflective for the pump light and the converted light, which improves the upward decoupling along the light emission direction H.

In the variant shown in FIGS. 3 and 4, planar contacts 19 are provided instead of bonding wires, which run in a plane parallel to the planar upper surface 21 of the substrate 5 and connect the electrical contacts of the light source 1 to electrical contacts of a power supply located further out in the same plane.

In the variant shown in FIGS. 5 and 6, the optoelectronic lighting device comprises an optoelectronic light source 1 for generating pump light and two conversion systems 3 for generating converted light by converting the pump light. The light source 1 is arranged between the two conversion systems 3. A respective longitudinal side of the light source 1 contacts a longitudinal side of a respective conversion system 3. For better heat dissipation, the conversion systems 3 and the light source 1 are each arranged directly on a thermally conductive substrate 5. The conversion systems contain fluorides such as LiF or BaF2, CaF2, whose refractive indices are similar to the polymer matrix material and have a high thermal conductivity. Thermal effects such as thermal quenching, which have a negative impact on the conversion of light, can thus be reduced or avoided.

Furthermore, a mirror coating 9 is arranged directly on the upper surface 7 of the light source 1. The mirror coating 9 can be in the form of a coating and, for example, a Bragg mirror. The mirror coating 9 can be transparent for the converted light, so that the converted light can be emitted upwards in the direction of the main emission direction H. Since two conversion systems 3 are provided, the converted light is emitted upwards from each conversion system 3, as indicated by the respective main direction of emission H shown.

In the variant shown in FIGS. 5 and 6, planar contacts 19 are again provided, which run in a plane parallel to the planar upper surface 21 of the substrate 5 and which connect the electrical contacts of the light source 1 to electrical contacts of a power supply located further out in the same plane.

An encapsulation 11 surrounds the light source 1 and the converters 3. The encapsulation 11 can be highly reflective for the pump light and the converted light, which improves the upward decoupling.

The variant of an optoelectronic lighting device shown in FIG. 7 comprises an optoelectronic light source 1 for generating pump light, a conversion system 3 for generating converted light by conversion of the pump light and thermally conductive substrate 5. The conversion system 3 is in turn arranged on the substrate 5 for better heat dissipation, and the light source 1 is arranged laterally above the conversion system 3.

As FIG. 7 shows, the upper surface of the substrate 3, on which the conversion system 3 is arranged, is divided into a flat area 25 and a rising area 27 adjoining the flat area 25. The rising area 27 forms a ramp that faces the upper surface 7 of the light source 1. This arrangement allows the conversion system 3 to be irradiated particularly well with pump light, and converted light can be reflected particularly well upwards by means of the rising area 27 of the substrate 5 and emitted via the upper surface of the device along the main radiation direction H. The substrate 5 can have a high reflectivity for the converted light and for the pump light. An encapsulation 11 that fills the volume between converter 3 and light source 1 is preferably transparent, both for converted light and for pump light.

As shown, the upper surface 7 of the light source 1 is aligned perpendicular to the upper surface 21 of the flat area 25 of the substrate 5. The bottom surface of the light source 1 is attached to a wall 29 extending perpendicular to the flat area 25 of the substrate 5. The wall 29 may, for example, be a wall of a submount that provides electrical connections for the light source 1. Preferably, the light source 1 is designed as a flip chip, so that the electrical contacts of the light source 1 face the wall 29.

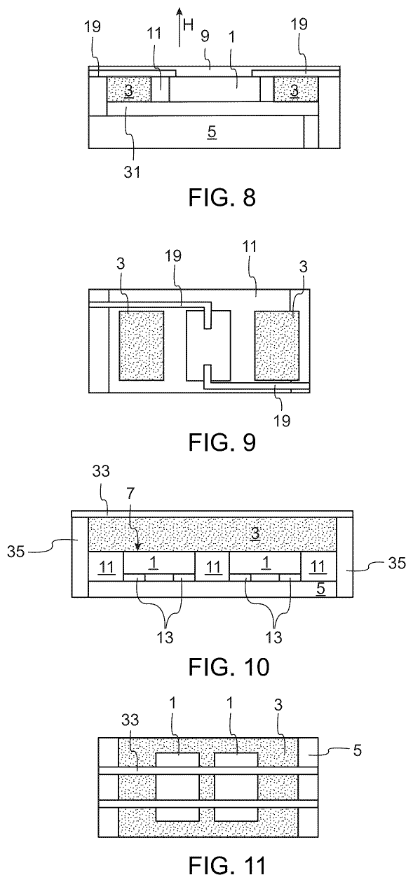

In the variant shown in FIGS. 8 and 9, the optoelectronic lighting device comprises an optoelectronic light source 1 for generating pump light, two converters 3 for generating converted light by converting the pump light and a thermally conductive substrate 5. The light source 1 is arranged laterally next to and between the two converters 3. A light-conducting layer 31, in particular with a grid structure, is formed between the substrate 5 and the light source 1 and the two converters 3 in order to conduct the pump light from the light source 1 to the conversion systems 3.

The light-conducting layer 31 and the underlying substrate 5 enable good dissipation of the heat generated in the conversion systems 3. Interfering thermal effects in the conversion systems 3 can thus be avoided or at least reduced. To improve the light conduction, an encapsulation 11 is provided between the light source 1 and the converters 3, which can be highly reflective for both the pump light and the converted light.

Planar contacts 19 can again be provided to supply power to the light source 1, as described above. In addition, an overhead mirror coating 9 can extend over the entire length and width of the device. The mirror coating 9 can reflect the pump light and be transparent for the converted light in order to allow light to be emitted upwards along the main direction of radiation H.

In the variant according to FIGS. 10 and 11, the optoelectronic lighting device shown comprises two optoelectronic light sources 1 for generating pump light, a conversion system 3 for generating converted light by converting the pump light, and a thermally conductive substrate 5. A heat-conducting layer 33 is provided above the conversion system 3, in particular directly above the conversion system 3, for dissipating heat from the conversion system 3. By means of the heat conducting layer 33, efficient dissipation of the heat generated in the converter 3 can be achieved. The heat-conducting layer 33 is designed as a transparent layer, so that emission of converted light through the heat-conducting layer 33 upwards out of the device is possible.

The light sources 1 are arranged on the substrate 5 and are designed as flip chips, so that their electrical contacts 13 point downwards and can be connected to contact points on the substrate 5 that are not shown.

The upper surfaces 7 of the light sources 1 can be flat, as shown, and the conversion system 3 is arranged directly on the flat upper surfaces 7. This allows the light generated by the light source 1 to be coupled directly into the respective converter 3. The light source 1 is preferably designed as a surface emitter for this purpose.

An encapsulation 11 surrounds the light sources 1 and the bottom surface of the converter 3. The encapsulation 11 can reflect the converted light and the pump light.

The heat-conducting layer 33 is in thermal contact with a housing wall 35 of the device at its respective outer edge. Heat build-up in the heat-conducting layer 33 can thus be avoided. In addition, excess heat can be dissipated via the housing wall 35.

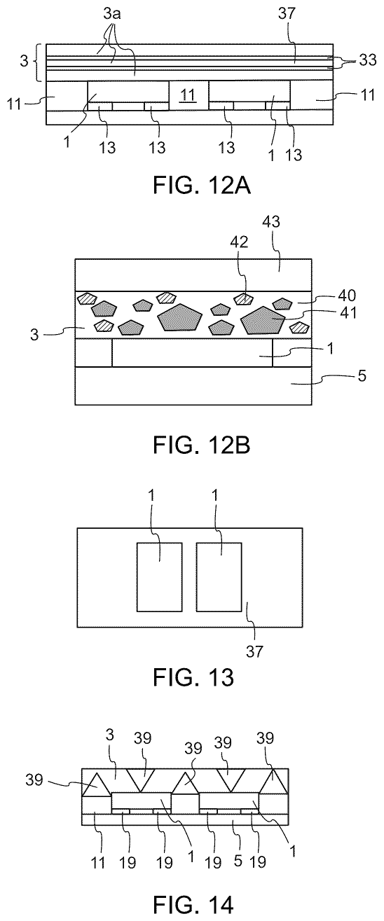

The variant of an optoelectronic lighting device shown in FIGS. 12A, 12B and 13 comprises two optoelectronic light sources 1 for generating pump light, at least one conversion system 3 for generating converted light by conversion of the pump light and a thermally conductive substrate 5. The conversion system 3 is designed in the form of a multilayer structure 37. The layers 3a each contain converter materials that are embedded in the polymer matrix material. In addition, the conversion system 3 comprises several transparent heat conducting layers 33 arranged to dissipate heat from the conversion system 3. These comprise transparent particles with a high thermal conductivity for the wave range of the converter materials. However, the particles can either be transparent for the pump light or reflective. The latter may be advantageous, as unconverted light is fed back to the converter layers in this way. The particles can be used to avoid or at least reduce undesirable thermal effects in the converter 3.

In the present embodiment example, the thicknesses of the converter layers and the heat-conducting layers 33 are different. The heat-conducting layers 33 can transport the heat generated not only upwards, but also away to the side. The latter is advantageous if the conversion system is laterally thermally connected to a heat sink.

FIG. 12B shows a variant in which the conversion system is mounted on a glass substrate 43. The glass substrate allows the conversion system 3 to be manufactured separately so that it is connected to the emission surface of the light source in a separate step.

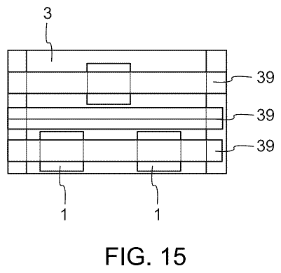

The variant of an optoelectronic lighting device shown in FIGS. 14 and 15 comprises two optoelectronic light sources 1 for generating pump light, a conversion system 3 for generating converted light by converting the pump light and a thermally conductive substrate 5. Several non-transparent heat-conducting elements 39 are arranged in the conversion system 3 to dissipate heat from the conversion system 3. The heat-conducting elements 39 also make it possible to avoid or at least reduce undesirable thermal effects in the converter 3.

A respective heat conducting element 39 can protrude through the converter 3 when viewed in a height direction, with the height direction running perpendicular to the upper surface of the substrate. Efficient heat dissipation over the entire height of the converter 3 can thus be achieved.

A respective heat conducting element 39 can have a triangular cross-section. Due to the triangular cross-section, a respective element is particularly suitable as a reflector for the light provided by the light source and/or for the converted light.

A respective heat element 39 can, as shown, be designed as an elongated, rod-shaped element, preferably with a triangular cross-section. Such a heat conducting rod can be fully or partially immersed in the converter 3 in order to enable the dissipation of heat. Particularly preferred is an arrangement of several parallel, spaced-apart heat conducting rods that are fully or partially immersed in the converter 3. Preferably, the thickness of the cross-section corresponds to the thickness of the conversion system 3.

A respective heat conducting element 39 can be made of a metal such as copper, silver or gold.

The conversion system 3 can be designed as a converter plate with a rectangular cross-section, for example.

The light source 1 can be an LED or an LED chip. The light source 1 can be an optoelectronic laser, such as a laser diode or a VCSEL.

1.-16. (canceled)

17. An optoelectronic lighting device comprising:
at least one optoelectronic light source configured to generate light;
at least one conversion system configured to convert the light into converted light;
a thermally conductive substrate,
wherein the conversion system is arranged on the substrate for heat dissipation,
wherein the light source is also arranged on the substrate above the conversion system or laterally next to the conversion system; and
a mirror coating arranged above the light source,
wherein the mirror coating is transparent to the converted light and/or reflective to the light, and
wherein the conversion system comprises a polymer matrix material in which a converter material and particles, which are substantially transparent to a wavelength of the converted light, are embedded, and which have a thermal conductivity which is at least 20 times higher than a thermal conductivity of the polymer matrix material.

18. The optoelectronic lighting device according to claim 17, wherein the particles comprise a material selected from the group consisting of salts of the VII main group, LiF, CaF2, NaF2, BaF2 and MgF2.

19. The optoelectronic lighting device according to claim 17, wherein a refractive index of the particles differs from a refractive index of the polymer matrix material by only 0.02 to 0.1.

20. The optoelectronic lighting device according to claim 17, wherein an amount of particles is in a range of from 10% to 50% by weight of the conversion system.

21. The optoelectronic lighting device according to claim 17, wherein an amount of particles is in a range of from 20wt % to 80wt % of the polymer matrix material.

22. The optoelectronic lighting device according to claim 17, wherein an average size of the particles is smaller than an average size of the converter material.

23. The optoelectronic lighting device according to claim 17, wherein the particles comprise a coating such that adhesion to the polymer matrix material is improved compared to adhesion of the particles without the coating to the polymer matrix material.

24. The optoelectronic lighting device according to claim 17, wherein the mirror coating is a Bragg mirror coating or a full mirror coating.

25. The optoelectronic lighting device according to claim 17,
wherein the light source comprises electrical contacts only on one side for a power supply, and
wherein the electrical contacts are planar contacts, which extend in a plane parallel to an upper surface of the substrate, or wherein the electrical contacts are bonding wires.

26. The optoelectronic lighting device according to claim 17, further comprising an encapsulation extending in a circumferential direction around the conversion system and/or the light source, wherein the encapsulation is configured to reflect the converted light and/or the light.

27. The optoelectronic lighting device according to claim 17, wherein, in an arrangement of the light source being laterally next to the at least one conversion system, at least two conversion systems are provided on the substrate and the light source is arranged between the two conversion systems.

28. The optoelectronic lighting device according to claim 17, wherein the substrate has a high reflectivity for the converted light and/or for the light.

29. The optoelectronic lighting device according to claim 17 wherein the conversion system comprises at least two layers, wherein a density of the particles and the converter material in the respective layers are different.

30. The optoelectronic lighting device according to claim 29, wherein the conversion system comprises at least one layer with the particles embedded in the polymer matrix material for vertical and lateral dissipation of heat from layers with converter material.

31. The optoelectronic lighting device according to claim 29, further comprising an encapsulation extending circumferentially around the light source and below the conversion system, wherein the encapsulation is configured to reflect the converted light and the light.

32. The optoelectronic lighting device according to claim 29, further comprising a heat conducting layer in thermal contact with a housing wall of the optoelectronic lighting device at its outer edge.
